(19) United States
(12) Patent Application Publication
(10) Pub. No.: US 2024/0260354 A1
(43) Pub. Date: Aug. 1, 2024

(54) DISPLAY PANEL AND DISPLAY DEVICE

(71) Applicant: LG DISPLAY CO., LTD., Seoul (KR)

(72) Inventors: EunJi Joo, Seoul (KR); HyunHaeng Lee, Paju-si (KR); Kiwoong Song, Paju-si (KR); HuSik Yoon, Seoul (KR)

(73) Assignee: LG DISPLAY CO., LTD., Seoul (KR)

(21) Appl. No.: 18/467,286

(22) Filed: Sep. 14, 2023

(30) Foreign Application Priority Data
Jan. 30, 2023 (KR) 10-2023-0011705

(51) Int. Cl. H10K 59/131

(52) U.S. Cl. CPC H10K 59/131

(57) ABSTRACT

A display panel and a display device. Specifically, there may be provided a display panel and a display device, capable of preventing a reduction in opening area by at least one active pattern disposed in a portion of at least one emission area among the plurality of emission areas and disposed in a portion of the non-emission area, wherein the active pattern includes at least one cutting line in an area corresponding to the emission area, and wherein the active pattern is electrically connected to one of the plurality of signal lines and is electrically connected to at least one transistor disposed in the on-emission area surrounding the emission area where the active pattern is disposed.

### CROSS-REFERENCE TO RELATED APPLICATION

This application claims the priority of Korean Patent Application No. 10-2023-0011705, filed on Jan. 30, 2023, which is hereby incorporated by reference in its entirety.

### BACKGROUND

### Field of the Disclosure

The present disclosure relates to a display panel and a display device.

### Description of the Background

A display device includes thin film transistors (TFTs), a plurality of conductive layers, and light emitting elements.

In the process of manufacturing such a display device, defects, such as bright spots or dark spots, may occur in some emission areas due to foreign matter or the like. Some display devices perform a repair process to prevent defects by disconnecting the emission area where the defect occurs from the circuit area that drives the emission area. However, this method may reduce the opening of the display device or the success rate of the repair process.

### SUMMARY

Accordingly, the present disclosure is to provide a display panel and a display device capable of preventing a reduction in opening area due to a repair pattern by using a transparent active pattern, which serves as a line, as the repair pattern.

The present disclosure is also to provide a display panel and a display device capable of preventing a reduction in success rate of repair process due to failure of a laser beam to arrive at the active pattern due to a polarization plate included in the display device by performing a repair process using a long-wavelength laser beam and using a transparent active pattern as the repair pattern.

Further, the present disclosure is to provide a display panel and a display device capable of preventing a reduction in success rate of repair process due to failure of a laser beam to arrive at the active pattern due to the color filter as the repair of active pattern is performed on the emission area where the color filter is not disposed.

In an aspect of the present disclosure, a display panel includes a substrate including a plurality of subpixels including an emission area and a non-emission area surrounding the emission area, a plurality of signal lines disposed on the substrate in the non-emission area, and at least one active pattern disposed in a portion of at least one emission area among the plurality of emission areas and disposed in a portion of the non-emission area, wherein the active pattern includes at least one cutting line in an area corresponding to the emission area, and wherein the active pattern is electrically connected to one of the plurality of signal lines and is electrically connected to at least one transistor disposed in the non-emission area surrounding the emission area where the active pattern is disposed.

In another aspect the present disclosure, a display device includes a substrate including a plurality of subpixels including an emission area and a non-emission area surrounding the emission area, a plurality of signal lines disposed on the substrate in the non-emission area, and at least one active pattern disposed in a portion of at least one emission area among the plurality of emission areas and disposed in a portion of the non-emission area, wherein the active pattern includes at least one cutting line in an area corresponding to the emission area, and wherein the active pattern is electrically connected to one of the plurality of signal lines and is electrically connected to at least one transistor disposed in the non-emission area surrounding the emission area where the active pattern is disposed.

According to various aspects of the disclosure, there may be provided a display panel and a display device capable of preventing a reduction in opening area due to a repair pattern by using a transparent active pattern, which serves as a line, as the repair pattern.

According to various aspects of the disclosure, there may be provided a display panel and a display device capable of preventing a reduction in success rate of repair process due to failure of a laser beam to arrive at the active pattern due to, e.g., a polarization plate included in the display device by performing a repair process using a long-wavelength laser beam and using a transparent active pattern as the repair pattern.

According to various aspects of the disclosure, there may be provided a display panel and a display device capable of preventing a reduction in success rate of repair process due to failure of a laser beam to arrive at the active pattern due to the color filter as the repair of active pattern is performed on the emission area where the color filter is not disposed.

It is to be understood that both the foregoing general description and the following detailed description are exemplary and explanatory and are intended to provide further explanation of the disclosure as claimed.

### BRIEF DESCRIPTION OF THE DRAWINGS

The above and other features, and advantages of the disclosure will be more clearly understood from the following detailed description, taken in conjunction with the accompanying drawings, in which:

FIG. 1 is a view illustrating a system configuration of a display device according to aspects of the disclosure;

FIG. 2 is an equivalent circuit diagram illustrating a subpixel of a display device according to aspects of the disclosure;

FIG. 3 is a plan view illustrating a portion of a display area of a display device according to aspects of the disclosure;

FIG. 4 is a view illustrating a cutting portion and an active layer of a display panel according to aspects of the disclosure;

FIGS. 5, 6, 7, 8, and 9 are views illustrating various shapes of first to fourth active patterns according to aspects of the disclosure;

FIG. 10 is a view illustrating an arrangement relationship between first to fourth active patterns and other components according to aspects of the disclosure;

FIG. 11 is a view illustrating a planar structure of a display panel according to aspects of the disclosure; and

FIG. 12 is a cross-sectional view illustrating a structure of a portion of a second emission area and a portion of a non-emission area.

### DETAILED DESCRIPTION

In the following description of examples or aspects of the disclosure, reference will be made to the accompanying drawings in which it is shown by way of illustration specific examples or aspects that may be implemented, and in which the same reference numerals and signs may be used to designate the same or like components even when they are shown in different accompanying drawings from one another. Further, in the following description of examples or aspects of the disclosure, detailed descriptions of well-known functions and components incorporated herein will be omitted when it is determined that the description may make the subject matter in some aspects of the disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the disclosure. Each of these terms is not used to define essence, order, sequence, or number of elements etc., but is used merely to distinguish the corresponding element from other elements.

When it is mentioned that a first element “is connected or coupled to”, “contacts or overlap with” etc. a second element, it should be interpreted that, not only may the first element “be directly connected or coupled to” or “directly contact or overlap with” the second element, but a third element may also be “interposed” between the first and second elements, or the first and second elements may “be connected or coupled to”, “contact or overlap with”, etc. each other via a fourth element. Here, the second element may be included in at least one of two or more elements that “are connected or coupled to”, “contact or overlap with”, etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “may”.

Hereinafter, various aspects of the disclosure are described in detail with reference to the accompanying drawings.

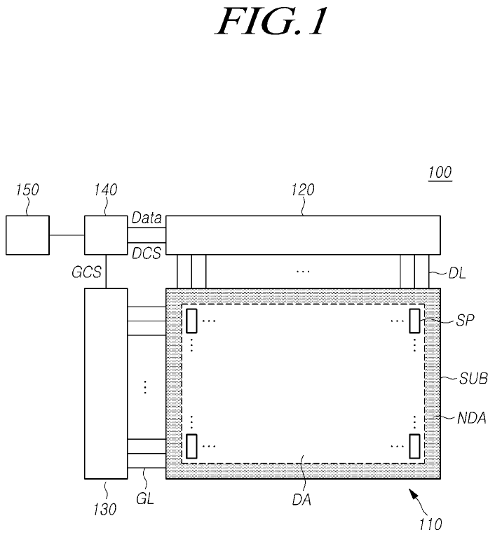

FIG. 1 is a view illustrating a system configuration of a display device according to aspects of the disclosure; Referring to FIG. 1, a display driving system of a display device 100 according to aspects of the disclosure may include a display panel 110 and display driving circuits for driving the display panel 110.

The display panel 110 may include a display area DA in which images are displayed and a non-display area NDA in which no image is displayed. The display panel 110 may include a plurality of subpixels SP disposed on a substrate SUB for image display. For example, the plurality of subpixels SP may be disposed in the display area DA. In some cases, at least one subpixel SP may be disposed in the non-display area NDA. At least one subpixel SP disposed in the non-display area NDA is also referred to as a dummy subpixel.

The display panel 110 may include a plurality of signal lines disposed on the substrate SUB to drive the plurality of subpixels SP. For example, the plurality of signal lines may include data lines DL, gate lines GL, driving voltage lines, and the like.

The plurality of data lines DL and the plurality of gate lines GL may cross each other. Each of the plurality of data lines DL may be disposed while extending in a first direction. Each of the plurality of gate lines GL may be disposed while extending in a direction crossing the first direction. Here, the first direction may be a column direction and the direction crossing the first direction may be a row direction. However, the embodiment of present disclosure is not limited thereto, the extending directions of data lines DL and gate lines GL can be exchanged.

The display driving circuits may include a data driving circuit 120, a gate driving circuit 130, and a controller 140 controlling the data driving circuit 120 and the gate driving circuit 130. The data driving circuit 120 may receive data signal from the controller 140 and convert the data signal into an analog data voltage Vdata. The data driving circuit 120 may output data signals (also referred to as data voltages) corresponding to an image signal to the plurality of data lines DL according to the timing at which the scan signal is applied through the gate line GL so that each of the plurality of subpixels SP emits light having brightness according to the data signal. The gate driving circuit 130 may generate a gate signal of a turn-on level voltage or a gate signal of a turn-off level voltage according to the control of the controller 140 and output the gate signals to the plurality of gate lines GL. The controller 140 may convert the input image data input from an external host 150 to meet the data signal format used in the data driving circuit 120 and supply the converted image data to the data driving circuit 120.

The data driving circuit 120 may include one or more source driver integrated circuits. Each source driver integrated circuit may include a shift register, a latch circuit, a digital-to-analog converter, an output buffer, and the like. For example, each source driver integrated circuit may be connected with the display panel 110 by a tape automated bonding (TAB) method or connected to a bonding pad of the display panel 110 by a chip on glass (COG) or chip on panel (COP) method or may be implemented by a chip on film (COF) method and connected with the display panel 110.

[25][29] The gate driving circuit may include one or more gate driver integrated circuits. The gate driving circuit 130 may be connected to the display panel 110 by a tape automatic bonding (TAB) method, connected to a bonding pad of the display panel 110 by a COG or COP method, connected to the display panel 110 by a COF method, or may be formed in the non-display area NDA of the display panel 110 by a gate in panel (GIP) method.

The display device 100 according to aspects of the disclosure may be a self-emission display device in which the display panel 110 emits light by itself. For example, the display device 100 according to aspects of the disclosure may be an organic light emitting diode display in which the light emitting element is implemented as an organic light emitting diode (OLED). As another example, the display device 100 according to aspects of the disclosure may be an inorganic light emitting display device in which the light emitting element is implemented as an inorganic material-based light emitting diode. As another example, the display device 100 according to aspects of the disclosure may be a quantum dot display device in which the light emitting element is implemented as a quantum dot which is self-emission semiconductor crystal.

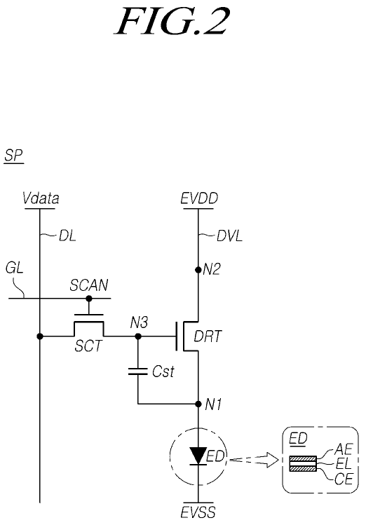

FIG. 2 is an equivalent circuit diagram illustrating a subpixel SP of a display device 100 according to aspects of the disclosure.

Referring to FIG. 2, in the display device 100 according to aspects of the disclosure, each subpixel SP may include a light emitting element ED and a pixel driving circuit SPC for driving the light emitting element ED. The pixel driving circuit SPC may include a driving transistor DRT, a scan transistor SCT, and a storage capacitor Cst, but is not limited thereto. The pixel driving circuit SPC may include other elements which are not shown.

The driving transistor DRT may control a current flowing to the light emitting element ED to drive the light emitting element ED. The scan transistor SCT may transfer the data voltage Vdata to the first node N1 which is the gate node of the driving transistor DRT. The storage capacitor Cst may be configured to maintain a voltage for a predetermined period of time.

The light emitting element ED may include an anode electrode AE and a cathode electrode CE, and a light emitting layer EL positioned between the anode electrode AE and the cathode electrode CE. The anode electrode AE may be electrically connected to the second node N2 of the driving transistor DRT.

A base voltage EVSS may be applied to the cathode electrode CE. The light emitting element ED may be, e.g., an organic light emitting diode OLED, an inorganic material-based light emitting diode LED, or a quantum dot light emitting element.

The driving transistor DRT is a transistor for driving the light emitting element ED, and may include a first node N1, a second node N2, and a third node N3. The first node N1 is a gate node and may be electrically connected to the source node or drain node of the scan transistor SCT. The second node N2 may be a source node or a drain node, and may be electrically connected to the anode electrode AE of the light emitting element ED. The third node N3 may be a drain node or a source node, and may be electrically connected to a driving voltage line DVL that supplies the driving voltage EVDD. For convenience of description, in the example described below, the second node N2 may be a source node and the third node N3 may be a drain node.

The scan transistor SCT may switch the connection between the data line DL and the first node N1 of the driving transistor DRT. In response to the scan signal SCAN supplied from the scan line SCL which is a kind of the gate line GL, the scan transistor SCT may control connection between the first node N1 of the driving transistor DRT and a corresponding data line DL among the plurality of data lines DL.

The drain node or source node of the scan transistor SCT may be electrically connected to a corresponding data line DL. The source node or drain node of the scan transistor SCT may be electrically connected to the first node N1 of the driving transistor DRT. The gate node of the scan transistor SCT may be electrically connected to the scan line SCL to receive the scan signal SCAN. The scan transistor SCT may be turned on by the scan signal SCAN of a turn-on level voltage and transfer the data voltage Vdata supplied from the data line DL to the first node N1 of the driving transistor DRT.

Referring to FIG. 2, the storage capacitor Cst may be configured between the first node N1 and second node N2 of the driving transistor DRT.

Referring to FIG. 2, in the display device 100 according to aspects of the disclosure, the pixel driving circuit SPC of each subpixel SP may further include a sensing transistor SENT. The sensing transistor SENT may switch the connection between the second node N2 of the driving transistor DRT and the reference voltage line RVL to which the reference voltage Vref is applied.

In response to the scan signal SCAN supplied from the scan line SCL, the sensing transistor SENT may control connection between the second node N2 of the driving transistor DRT electrically connected to the anode electrode AE of the light emitting element ED and a corresponding reference voltage line RVL among the plurality of reference voltage lines RVL. In FIG. 2, the gate node of the sensing transistor SENT and the gate node of the scan transistor SCT are connected to the same scan line SCL, but this is merely an example for convenience of description, and they may be connected to different scan lines SCL.

The drain node or source node of the sensing transistor SENT may be electrically connected to the reference voltage line RVL. The source node or drain node of the sensing transistor SENT may be electrically connected to the second node N2 of the driving transistor DRT and may be electrically connected to the anode electrode AE of the light emitting element ED. The gate node of the sensing transistor SENT may be electrically connected to the scan line SCL to receive the scan signal SCAN.

Each of the driving transistor DRT, the scan transistor SCT, and the sensing transistor SENT may be an n-type transistor or a p-type transistor. Here, when the transistor is an n-type transistor, the turn-on level voltage may be a high level voltage, and the turn-off level voltage may be a low level voltage. When the transistor is a p-type transistor, the turn-on level voltage may be a low level voltage and the turn-off level voltage may be a high level voltage.

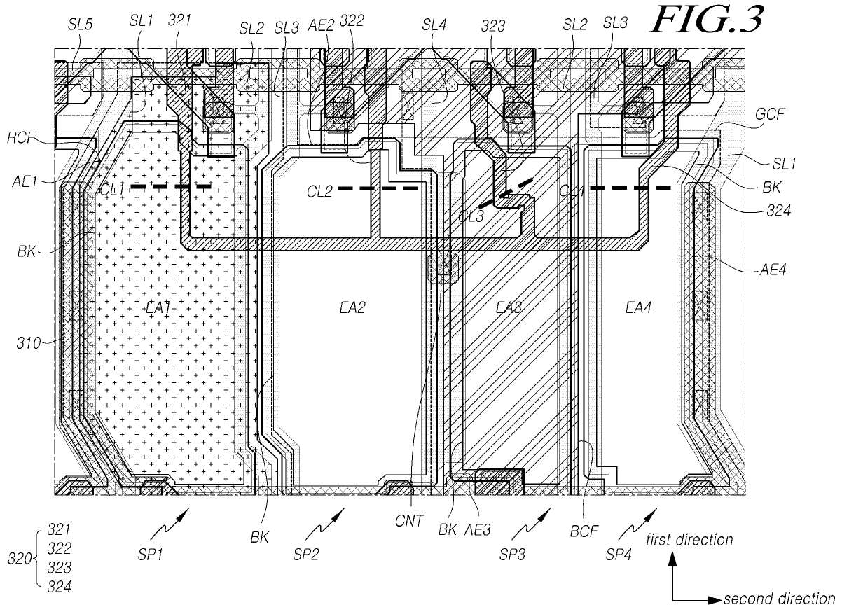

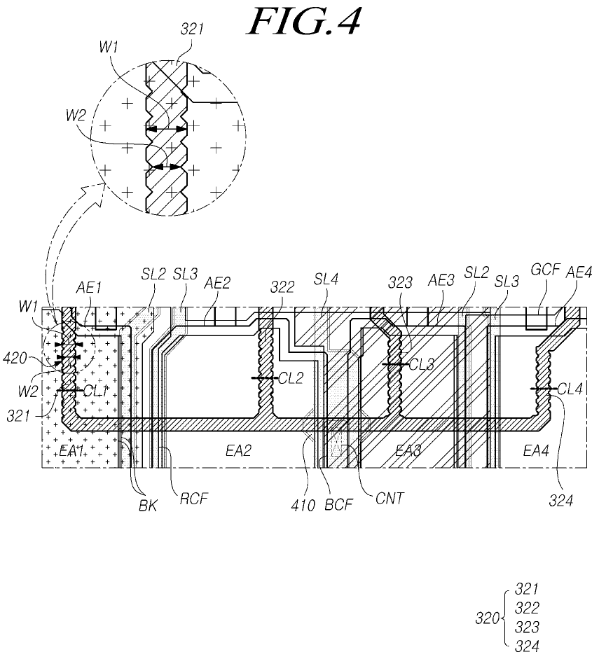

FIG. 3 is a plan view illustrating a portion of a display area of a display device according to aspects of the disclosure. FIG. 4 is a view illustrating a cutting portion and an active layer of a display panel according to aspects of the disclosure.

Referring to FIG. 3, the display panel 110 according to aspects of the disclosure may include a plurality of subpixels SP1, SP2, SP3, and SP4.

The subpixels SP1, SP2, SP3, and SP4 may include emission areas EA1, EA2, EA3, and EA4, respectively. For example, as illustrated in FIG. 3, a first subpixel SP1 may include a first emission area EA1, a second subpixel SP2 may include a second emission area EA2, a third subpixel SP3 may include a third emission area EA3, and a fourth subpixel SP4 may include a fourth emission area EA4.

The first emission area EA may be a red emission area, the second emission area EA2 may be a white emission area, the third emission area EA3 may be a blue emission area, and the fourth emission area EA4 may be a green emission area, but aspects of the disclosure are not limited thereto. The first to fourth emission area may be other color emission areas.

The display panel 110 may include a non-emission area surrounding a plurality of emission areas EA1, EA2, EA3, and EA4.

The plurality of emission areas EA1, EA2, EA3, and EA4 may correspond to the opening of the bank BK, and the non-emission area may be an area in which the bank BK is disposed. That is to say, as an example, banks BK are disposed to define the plurality of emission areas EA1, EA2, EA3, and EA4.

A plurality of signal lines, a plurality of transistors, and a plurality of storage capacitors for driving the light emitting elements disposed in the plurality of emission areas EA1, EA2, EA3, and EA4 may be disposed in the non-emission area.

For example, referring to FIG. 3, first to fifth signal lines SL1, SL2, SL3, SL4, and SL5 may be disposed in the non-emission area of the display panel 110.

Referring to FIG. 3, the first to fourth signal lines SL1, SL2, SL3, and SL4 may be disposed to be spaced apart from each other and extend in a first direction.

The first signal line SL1 may be a driving voltage line, the second and third signal lines SL2 and SL3 may be data lines, and the fourth signal line SL4 may be a reference voltage line, but aspects of the disclosure are not limited thereto.

The first signal line SL1 may be electrically connected to the extension line 310 disposed on the first signal line SL1.

The fifth signal line SL5 may be disposed to extend in a second direction that is a direction crossing the first direction. The fifth signal line SL5 may overlap with the first to fourth signal lines SL1, SL2, SL3, and SL4.

The fifth signal line SL5 may be a scan line, but aspects of the disclosure are not limited thereto.

Referring to FIG. 3, the display panel 110 may include a plurality of anode electrodes AE1, AE2, AE3, and AE4 respectively overlapping with the first to fourth emission areas EA1, EA2, EA3, and EA4.

Specifically, the first emission area EA1 of the first subpixel SP1 may overlap with the first anode electrode AE1, and the second emission area EA2 of the second subpixel SP2 may overlap with the second anode electrode AE2. Further, the third emission area EA3 of the third subpixel SP3 may overlap with the third anode electrode AE3, and the fourth emission area EA4 of the fourth subpixel SP4 may overlap with the fourth anode electrode AE4.

Referring to FIG. 3, the first emission area EA1 may overlap with a first color filter RCF, the third emission area EA3 may overlap with a second color filter BCF, and the fourth emission area EA4 may overlap with a third color filter GCF. Further, a color filter may not be disposed in the second emission area EA2, but aspects of the disclosure are not limited thereto. A color filter may not be disposed in emission areas other than the second emission area EA2.

Referring to FIG. 3, the display panel 110 according to aspects of the disclosure may include a non-emission area and an active pattern 320 overlapping with the emission areas EA1, EA2, EA3, and EA4.

The active pattern 320 may be disposed on the same layer as the active layer included in the transistor used to drive the light emitting diode ED disposed in each of the subpixels SP1, SP2, SP3, and SP4.

The active pattern 320 may include an oxide semiconductor material. The oxide semiconductor material is a semiconductor material produced by controlling conductivity and adjusting the band gap through doping an oxide material, and may generally be a transparent semiconductor material having a wide band gap. For example, the oxide semiconductor material may include indium gallium zinc oxide (IGZO), zinc oxide (ZnO), indium gallium oxide (IGO), indium zinc oxide (IZO), cadmium oxide (CdO), indium oxide (InO), zinc tin oxide (ZTO), zinc indium tin oxide (ZITO), indium gallium zinc tin oxide (IGZTO), and the like.

The active pattern 320 may serve as a line to receive various signals in the subpixel.

Accordingly, the oxide semiconductor material may be in a state in which the active pattern 320 is rendered conductive in at least a partial area. For example, the active pattern 320 may be rendered conductive in a process of dry-etching a gate insulation film that may be disposed on the active pattern 320, but the process of rendering the active pattern 320 conductive is not limited thereto. Accordingly, the oxide semiconductor material may be in a state in which the active pattern 320 is rendered conductive in at least a partial area.

The active pattern 320 may include a first active pattern 321, a second active pattern 322, a third active pattern 323, and a fourth active pattern 324.

Specifically, referring to FIGS. 3 and 4, the active pattern 320 may be electrically connected to the fourth signal line SL4 through a contact hole CNT, but embodiments of the disclosure are not limited thereto. The active pattern 320 may be electrically connected to other signal lines.

The active pattern 320 may include the first active pattern 321 branched to the first subpixel SP1. Further, the active pattern 320 may include the second active pattern 322 branched to the second subpixel SP2. The active pattern 320 may include the third active pattern 323 branched to the third subpixel SP3. The active pattern 320 may include the fourth active pattern 324 branched to the fourth subpixel SP4.

The first to fourth active patterns 321, 322, 323, and 324 may be electrically connected to a sensing transistor SENT (see FIG. 2) disposed in each of the subpixels SP1, SP2, SP3, and SP4. In other words, a signal applied from the fourth signal line SL4 may be supplied to the first to fourth subpixels SP1, SP2, SP3, and SP4 through the first to fourth active patterns 321, 322, 323, and 324.

Specifically, referring to FIG. 3, the active pattern 320 may include a body portion connected to the fourth signal line SL4 and extending in the second direction, and the body portion of the active pattern 320 may overlap with the first to fourth emission areas EA1, EA2, EA3, and EA4. Further, each of the first to fourth active patterns 321, 322, 323, and 324 may be branched from the body portion of the active pattern 320, and the active patterns may be disposed in the first to fourth emission areas EA1, EA2, EA3, and EA4, respectively.

At least one of the first to fourth emission areas EA1, EA2, EA3, and EA4 may overlap with a repair area.

The repair area may include a portion of an area in which at least one of the first to fourth active patterns 321, 322, 323, and 324 is disposed.

For example, the repair area overlapping with the first emission area EA1 may be an area corresponding to at least a portion of the area in which the first active pattern 321 is disposed. The repair area overlapping with the second emission area EA2 may be an area corresponding to at least a portion of the area in which the second active pattern 322 is disposed. The repair area overlapping with the third emission area EA3 may be an area corresponding to at least a portion of the area in which the third active pattern 323 is disposed. The repair area overlapping with the fourth emission area EA4 may be an area corresponding to at least a portion of the area in which the fourth active pattern 324 is disposed.

Referring to FIGS. 3 and 4, the first to fourth active patterns 321, 322, 323, and 324 may serve as repair patterns in an area overlapping with the emission area.

In the process of manufacturing the display panel included in the display device, each subpixel may be defective due to a foreign object or the like, and the defective subpixel may cause a dark spot or a defective bright spot.

As described above, when a subpixel is defective, the defective subpixel may be stopped from operating for repair purposes.

In the display device according to aspects of the disclosure, the active patterns 321, 322, 323, and 324 electrically connected to the fourth signal line SL4 may be disposed in each subpixel, and the at least one active pattern may include at least one cutting area CL.

FIGS. 3 and 4 illustrate a configuration in which one active pattern includes one cutting area CL, but aspects of the disclosure are not limited thereto. For example, at least one of the first to fourth active patterns 321, 322, 323, and 324 may include at least two cutting areas CL overlapping with the emission area.

A laser beam may be radiated to the cutting area CL of the active patterns 321, 322, 323, and 324, and the area irradiated with the laser beam may be electrically disconnected from other components, so that no signal may be applied to the corresponding subpixel.

In other words, the cutting area CL of the first to fourth active patterns 321, 322, 323, and 324 may be a repair area of the subpixel in which each active pattern is disposed.

Referring to FIG. 3, the first active pattern 321 may include a first cutting area CL1, the second active pattern 322 may include a second cutting area CL2, the third active pattern 323 may include a third cutting area CL3, and the fourth active pattern 324 may include a fourth cutting area CL4.

The first cutting area CL1 may be disposed in the first emission area EA1, the second cutting area CL2 may be disposed in the second emission area EA2, the third cutting area CL3 may be disposed in the third emission area EA3, and the fourth cutting area CL4 may be disposed in the fourth emission area EA4.

For example, when a defect occurs in the first subpixel SP1, an electrical connection between the fourth signal line SL4 and the first subpixel SP1 may be disconnected by radiating a laser beam to the first cutting area CL1 of the first active pattern 321.

As described above, the cutting areas CL1, CL2, CL3, and CL4 capable of repairing the subpixels may be disposed to overlap with the emission areas EA1, EA2, EA3, and EA4, thereby providing a repair area without decreasing the aperture ratio.

In particular, even when light emitted from the emission areas EA1, EA2, EA3, and EA4 of the display area DA of the display panel 110 is emitted toward the substrate in which the plurality of signal lines and the plurality of transistors are disposed, loss of the aperture ratio may be prevented as transparent first to fourth active patterns 321, 322, 323, and 324 are disposed in an area corresponding to the emission areas EA1, EA2, EA3, and EA4.

As described above, the first to fourth active patterns 321, 322, 323, and 324 including the oxide semiconductor material may be utilized as transparent lines, and due to the transparent characteristics, they may be difficult to see during the repair process.

Accordingly, as illustrated in FIG. 4, at least one opaque pattern 410 may be disposed on the substrate. The opaque pattern 410 may include a metal, but aspects of the disclosure are not limited thereto.

Specifically, the opaque pattern 410 may overlap with the fourth signal line SL4, and may also overlap with the active pattern 320, but is not limited thereto, and the opaque pattern 410 may overlap other signal lines. Here, the opaque pattern 410 may overlap with the active pattern 320 even in an area where the fourth signal line SL4 does not overlap with the active pattern 320.

A contact hole CNT to which the fourth signal line SL4 and the active pattern 320 are connected may be disposed in the area overlapping with the opaque pattern 410.

Since the opaque pattern 410 is visible even during the repair process, the opaque pattern 410 may overlap with a portion of the transparent active pattern 320, so that it is possible to identify a portion of the position of the active pattern 320 and radiate a laser beam to a desired position.

Meanwhile, when a repair process is performed through the metal layer, a laser beam having a longer wavelength may be used than that used in a repair process using an active pattern including an oxide semiconductor material.

When the repair process is performed using a laser beam having a long wavelength, not only the repair pattern but also other lines or electrodes including metal may fail to operate normally due to the influence of the laser beam.

On the other hand, when the active pattern including the oxide semiconductor material is used as the repair pattern, the repair process may be performed using a short-wavelength laser beam, but the short-wavelength laser beam may not pass through the polarization .plate disposed on at least one surface of the display panel 110, and thus the repair pattern may not be properly cut.

Accordingly, as illustrated in FIG. 4, at least one of the first to fourth active patterns 321, 322, 323, and 324 may have a shape different from that of the area other than the repair area in the repair area (i.e., the area that may be irradiated with a laser beam during repair in the area in which the active pattern overlaps with the emission area). Accordingly, even when a long-wavelength laser beam is used (e.g., a laser beam wavelength used to repair a metal layer), the first to fourth active patterns 321, 322, 323, and 324 including an oxide semiconductor material may be cut.

At least one of the first to fourth active patterns 321, 322, 323, and 324 may include a plurality of protrusions 420 in an area overlapping with the emission area.

Specifically, referring to FIG. 4, a plurality of protrusions 420 may be disposed on one side surface of the first to fourth active patterns 321, 322, 323, and 324 and another side surface facing the one side surface at plan view.

As described above, the first width W1 of the areas of the first to fourth active patterns 321, 322, 323, and 324 in which the protrusions 420 are disposed on two opposite side surfaces at plan view may be larger than the second width W2 of the areas of the first to fourth active patterns 321, 322, 323, and 324 corresponding to the areas between the protrusions 420 and the other protrusions 420 adjacent to the protrusions 420.

During the repair process, each of the first to fourth active patterns 321, 322, 323, and 324 may be cut in an area of the first to fourth active patterns 321, 322, 323, and 324 corresponding to an area between the protrusion 420 and another protrusion 420 adjacent to the protrusion 420.

In other words, the cutting line CL may be positioned in an area in which the first to fourth active patterns 321, 322, 323, and 324 have the second width W2 in the emission area, and the area in which the first to fourth active patterns 321, 322, 323, and 324 have the second width W2 may be positioned between the areas in which the first to fourth active patterns 321, 322, 323, and 324 have the first width W1.

As the areas in which the first to fourth active patterns 321, 322, 323, and 324 have the second width W2 are positioned between the areas in which the first to fourth active patterns 321, 322, 323, and 324 have the first width W1, the rigidity of the cutting area CL of the first to fourth active patterns 321, 322, 323, and 324 may be lower than that of the area other than the cutting area CL. Accordingly, even when a long-wavelength laser beam is radiated to the cutting area CL, the first to fourth active patterns 321, 322, 323, and 324 including the oxide semiconductor material may be repaired.

FIG. 4 illustrates a structure in which the first to fourth active patterns 321, 322, 323, and 324 overlapping with the emission area include a plurality of protrusions 420 in some of the areas overlapping with the emission area, but the structure of the first to fourth active patterns 321, 322, 323, and 324 according to aspects of the disclosure is not limited thereto.

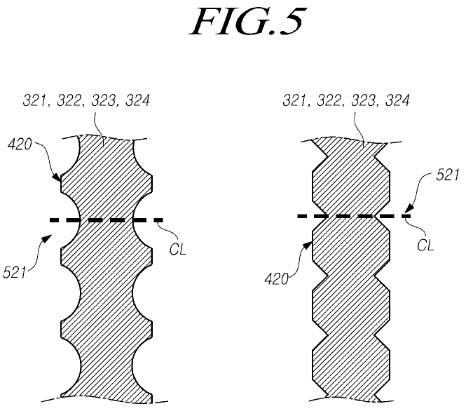

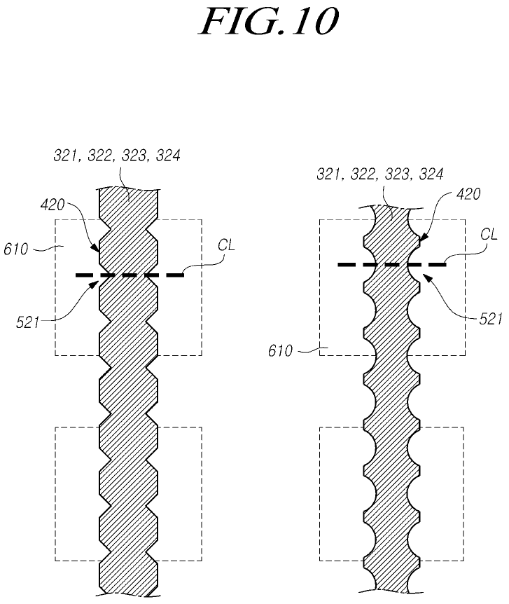

FIGS. 5 to 9 are views illustrating various shapes of first to fourth active patterns according to aspects of the disclosure, and FIG. 10 is a view illustrating an arrangement relationship between the first to fourth active patterns and other components according to aspects of the disclosure.

The area of the active patterns illustrated in FIGS. 5 to 10 may be an area disposed in a partial area overlapping with the emission area.

Referring to FIGS. 5 to 10, the first to fourth active patterns 321, 322, 323, and 324 may include a plurality of protrusions 420 and a plurality of depressions 521 in the emission area of the subpixel. Each of the first to fourth active patterns 321, 322, 323, and 324 may include at least one cutting line CL.

Referring to FIG. 5, a plurality of protrusions 420 and a plurality of depressions 521 may be provided on two opposite side surfaces of the first to fourth active patterns 321, 322, 323, and 324. The plurality of protrusion portions 420 and the plurality of depressions 521 may be alternately disposed.

Specifically, referring to FIG. 5, at least one depression 521 provided on one side of the first to fourth active patterns 321, 322, 323, and 324 may be disposed to face one depression 521 provided on the other side of the first to fourth active patterns 321, 322, 323, and 324. Further, the at least one protrusion 420 provided on one side of the first to fourth active patterns 321, 322, 323, and 324 may be disposed to face the one protrusion 420 provided on the other side of the first to fourth active patterns 321, 322, 323, and 324.

The arrangement relationship between the protrusion 420 and the depression 521 according to aspects of the disclosure is not limited thereto.

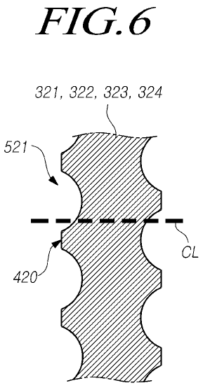

For example, referring to FIG. 6, a portion of at least one depression 521 provided on one side of the first to fourth active patterns 321, 322, 323, and 324 may be disposed to face a portion of one depression 521 provided on the other side of the first to fourth active patterns 321, 322, 323, and 324. Further, a portion of the at least one protrusion 420 provided on one side of the first to fourth active patterns 321, 322, 323, and 324 may be disposed to face a portion of the one depression 521 provided on the other side of the first to fourth active patterns 321, 322, 323, and 324.

Referring to FIGS. 5 and 6, the first to fourth active patterns 321, 322, 323, and 324 according to aspects of the disclosure may include at least one cutting line CL. The cutting line CL may be provided to cross one depression 521 disposed on one side of each of the first to fourth active patterns 321, 322, 323, and 324 and the depression 521 disposed on the other side on the flat surface.

Accordingly, the cutting line CL may be provided in an area having a narrow width of each of the first to fourth active patterns 321, 322, 323, and 324, and thus the cutting line CL may be provided in an area having low rigidity, and thus the first to fourth active patterns 321, 322, 323, and 324 may be easily cut through a laser beam having a long wavelength.

Here, the widths of the first to fourth active patterns 321, 322, 323, and 324 may mean the shortest distance between two opposite side surfaces of each of the first to fourth active patterns 321, 322, 323, and 324.

Further, referring to FIGS. 5 to 7, the depression 521 according to aspects of the disclosure may be formed in various shapes.

For example, as illustrated in FIGS. 5 and 6, the depression 521 may have the semicircle with one side open or the triangular shape with one side open at plan view, but the shape of the depression 521 according to aspects of the disclosure is not limited thereto.

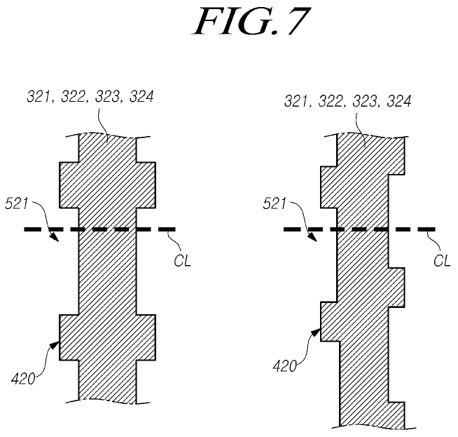

For example, as illustrated in FIG. 7, it may have a rectangular shape with one side open, but is not limited thereto, and may have a polygonal shape with one side open.

Further, referring to FIGS. 5 to 7, the size of one depression 521 may be larger than the size of one protrusion 420. In this case, since the area in which the cutting area CL may exist in the emission area increases, the first to fourth active patterns 321, 322, 323, and 324 may be easily cut in the repair process.

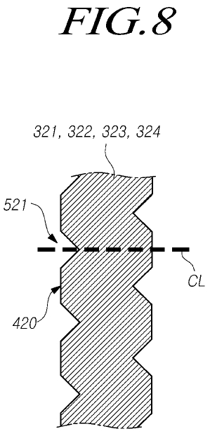

Further, the shapes of the first to fourth active patterns 321, 322, 323, and 324 according to aspects of the disclosure are not limited thereto, and as illustrated in FIG. 8, at least one depression 521 provided on one side of the first to fourth active patterns 321, 322, 323, and 324 may be disposed to face one protrusion 420 provided on the other side of the first to fourth active patterns 321, 322, 323, and 324.

In this case, the cutting line CL may be provided to cross one depression 521 provided on one side of the first to fourth active patterns 321, 322, 323, and 324 and one protrusion 420 provided on the other side.

Even if the depressions 521 are provided on only one side of the first to fourth active patterns 321, 322, 323, and 324, the widths of the first to fourth active patterns 321, 322, 323, and 324 at plan view may be narrower than the areas in which the protrusions 420 are provided on two opposite sides of the first to fourth active patterns 321, 322, 323, and 324, thereby reducing the rigidity of the first to fourth active patterns 321, 322, 323, and 324.

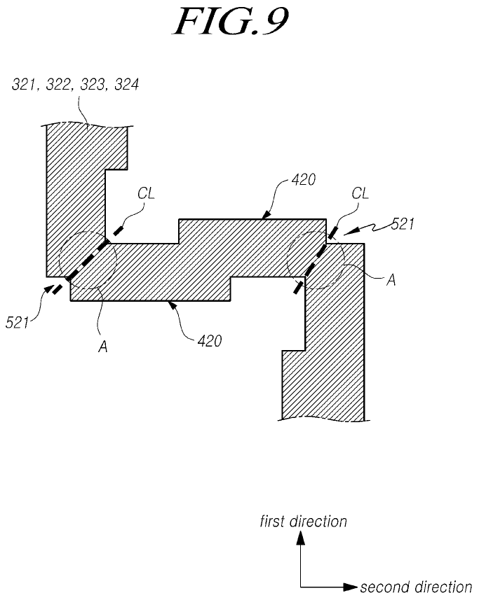

Also, as illustrated in FIG. 9, the first to fourth active patterns 321, 322, 323, and 324 may have at least one bent portion A.

In the first active pattern 321, e.g., the bent portion A may be an area where a portion of the first active pattern 321 extending in the first direction and a portion of the first active pattern 321 extending in the second direction crossing the first direction cross each other.

As illustrated in FIG. 9, the bent portion A may include a depression 521 that is a concave with respect to other areas (e.g., protrusions). The bent portion A may be provided with a cutting line CL.

The first to fourth active patterns 321, 322, 323, and 323 according to aspects of the disclosure may overlap with other opaque components in a portion of the emission area.

For example, referring to FIG. 10, some of the first to fourth active patterns 321, 322, 323, and 323 may overlap with at least one metal layer 610.

Further, a cutting line CL overlapping with at least one depression 521 of the first to fourth active patterns 321, 322, 323, and 323 may be provided in an area overlapping with the metal layer 610.

The position of the cutting line CL may be easily recognized through the metal layer 610.

The metal layer 610 may be a component in which the light blocking layer disposed in the non-emission area NEA of the subpixel partially extends, but aspects of the disclosure are not limited thereto, but any component may be used that allows a component capable of identifying the position of the cutting line CL to overlap with some of the first to fourth active patterns 321, 322, 323, and 323.

In FIGS. 3 to 10, a structure in which the first to fourth active patterns 321, 322, 323, and 324 have at least one cutting line CL in the first to fourth emission areas EA1, EA2, EA3, and EA4, respectively, has been described, but aspects of the disclosure are not limited thereto.

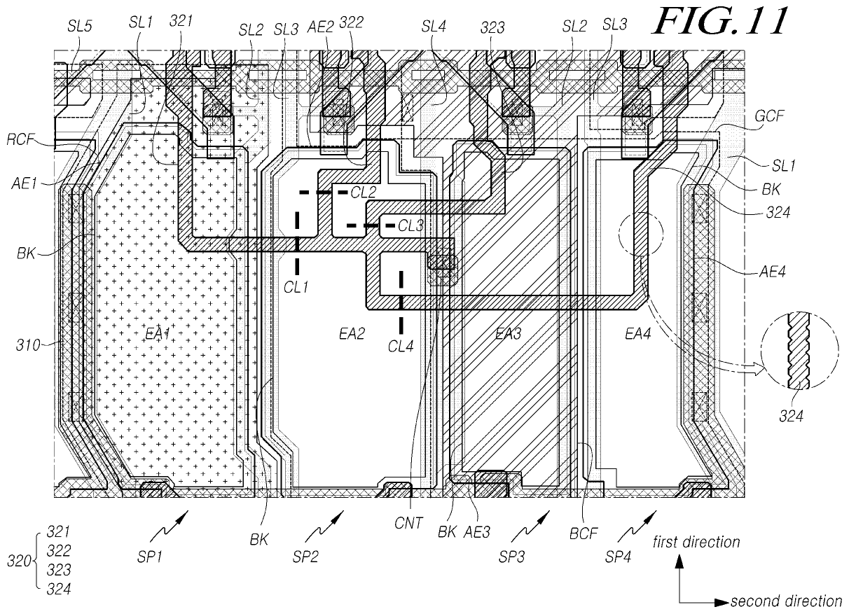

FIG. 11 is a view illustrating a planar structure of a display panel according to aspects of the disclosure.

Referring to FIG. 11, the active pattern 320 including the first to fourth active patterns 321, 322, 323, and 324 may be electrically connected to the fourth signal line SL4 through the contact hole CNT.

The first active pattern 321 may extend to the circuit area of the first subpixel SP1, the second active pattern 322 may extend to the circuit area of the second subpixel SP2, the third active pattern 323 may extend to the circuit area of the third subpixel SP3, and the fourth active pattern 324 may extend to the circuit area of the fourth subpixel SP4.

A plurality of transistors, a plurality of signal lines, a storage capacitor, and the like for driving the light emitting element ED may be disposed in a circuit area of each of the subpixels SP1, SP2, SP3, and SP4.

Referring to FIG. 11, the respective portions of the first to fourth active patterns 321, 322, 323, and 324 may be disposed to overlap with the first to fourth emission areas EA1, EA2, EA3, and EA4.

Referring to FIG. 11, at least one of the first to fourth active patterns 321, 322, 323, and 324 may include a plurality of protrusions in an area overlapping with the emission area.

For example, at least one of the first to fourth active patterns 321, 322, 323, and 324 may have the structure illustrated in FIGS. 5 to 10 in the area overlapping with the emission area.

Specifically, referring to FIG. 11, the first active pattern 321 may be disposed in a portion of the first emission area EA1, a portion of the second emission area EA2, and a portion of the non-emission area of the first subpixel SP1. Accordingly, the first active pattern 321 electrically connected to the fourth signal line SL4 positioned between the second emission area EA2 and the third emission area EA3 may extend to the circuit area of the first subpixel SP1 to serve to transfer the signal of the fourth signal line SL4 to the circuit area of the first subpixel SP1.

The second active pattern 322 may be disposed in a portion of the second emission area EA2 and a portion of the non-emission area of the second subpixel SP2. Accordingly, the second active pattern 322 electrically connected to the fourth signal line SL4 may extend to the circuit area of the second subpixel SP2 to serve to transfer the signal of the fourth signal line SL4 to the circuit area of the second subpixel SP2.

The third active pattern 323 may be disposed in a portion of the second emission area EA2, a portion of the third emission area EA3, and a portion of the non-emission area of the third subpixel SP3. Accordingly, the third active pattern 323 electrically connected to the fourth signal line SL4 may extend to the circuit area of the third subpixel SP3 to serve to transfer the signal of the fourth signal line SL4 to the circuit area of the third subpixel SP3.

The fourth active pattern 324 may be disposed in a portion of the second emission area EA2, a portion of the third emission area EA3, a portion of the fourth emission area EA4, and a portion of the non-emission area of the fourth subpixel SP4. The fourth active pattern 324 electrically connected to the fourth signal line SL4 may extend to the circuit area of the fourth subpixel SP4 and may serve to transfer the signal of the fourth signal line SL4 to the circuit area of the fourth subpixel SP4.

Further, each of the first to fourth active patterns 321, 322, 323, and 324 may include at least one cutting line CL.

Specifically, referring to FIG. 11, each of the first to fourth cutting lines CL1, CL2, CL3, and CL4 of the first to fourth active patterns 321, 322, 323, and 324 may be disposed in the second emission area EA2.

Here, the second emission area EA2 in which the first to fourth cutting lines CL1, CL2, CL3, and CL4 are positioned may be an emission area in which no color filter is disposed, and the first emission area EA1, the third emission area EA3, and the fourth emission area EA4 in which the first to fourth cutting lines CL1, CL2, CL3, and CL4 are not positioned may be an area in which color filters RCF, BCF, and GCF are disposed.

As described above, since the first to fourth cutting lines CL1, CL2, CL3, and CL4 overlap with the second emission area EA2 in which the color filter is not disposed, a reduction in repair success rate due to the laser beam unable to sufficiently reach the first to fourth active patterns 321, 322, 323, and 324 since the color filters RCF, BCF, and GCF may absorb a portion of the laser beam during the repair process can be prevented or reduced.

Since the respective cutting lines CL1, CL2, CL3, and CL4 of the first to fourth active patterns 321, 322, 323, and 324 are provided in the second emission area EA2, the shapes of the first to fourth active patterns 321, 322, 323, and 324 may be different from each other.

For example, as illustrated in FIG. 11, at least two of the first to fourth active patterns 321, 322, 323, and 324 may have different number of bent portions in the area overlapping with the emission areas EA1, EA2, EA3, and EA4.

The first to fourth active patterns 321, 322, 323, and 324 may be designed to serve as lines connected to the fourth signal line CL4 while the cutting lines CL1, CL2, CL3, and CL4 are provided in the second emission area EA2 to enhance the success rate of the repair process.

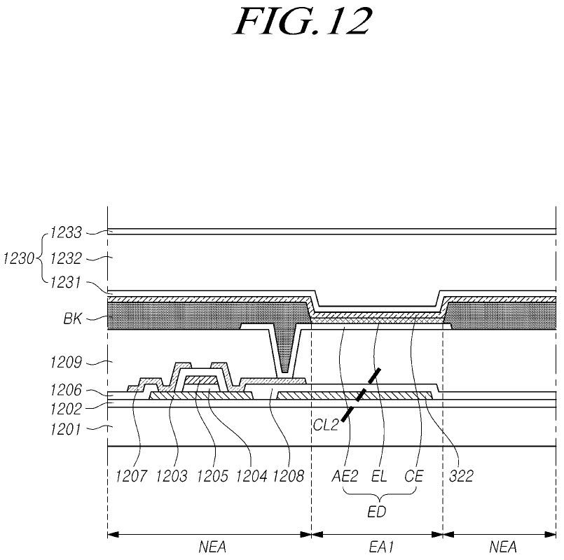

The structure of a portion of the second emission area EA2 and a portion of the non-emission area of FIG. 11 is described below with reference to FIG. 12.

FIG. 12 is a cross-sectional view illustrating the structure of a portion of a second emission area EA2 and a portion of a non-emission area of a display panel according to exemplary embodiments of the disclosure.

Referring to FIG. 12, the display panel 110 according to aspects of the disclosure may include at least one thin film transistor disposed on the substrate 1201 and a light emitting element ED disposed on the thin film transistor. The substrate 1201 may be at least one of a metal substrate, a plastic substrate, and a glass substrate.

The thin film transistor may include an active layer 1203, a gate electrode 1205, a source electrode 1207, and a drain electrode 1208.

The light emitting element ED may include an anode electrode AE, a light emitting layer EL, and a cathode electrode CE.

Specifically, a buffer layer 1202 may be disposed on the substrate 1201.

The buffer layer 1202 may include an inorganic insulating material, such as silicon oxide (SiOx), silicon nitride (SiNx), and silicon oxynitride (SiON), but the disclosure is not limited thereto.

In FIG. 12, the buffer layer 1202 has a single-layer structure, but the buffer layer 1202 of the disclosure may have a multi-layer structure.

If the buffer layer 1202 has a multi-layer structure, layers including at least two inorganic insulating materials among inorganic materials, such as silicon oxide (SiOx), silicon nitride (SiNx), and silicon oxynitride (SiON), may be alternately disposed, but the disclosure is not limited thereto.

An active layer 1203 of the thin film transistor may be disposed on the buffer layer 1202.

The active layer 1203 may be various types of semiconductor layers. For example, the active layer 303 may be one selected from among an oxide semiconductor, an amorphous silicon semiconductor, and a polysilicon semiconductor, but the disclosure is not limited thereto. For example, the oxide semiconductor material may be formed of any one of indium gallium zinc oxide (IGZO), indium zinc oxide (IZO), indium gallium tin oxide (IGTO), and indium gallium oxide (IGO), but is not limited thereto. The polycrystalline semiconductor may be formed of a low temperature poly silicon (LTPS) having a high mobility, but is not limited thereto.

FIG. 12 illustrates a structure in which the active layer 1203 is a single layer, but the structure according to aspects of the disclosure is not limited thereto, and the active layer 1203 may be formed in a multilayer structure.

Further, when the active layer 1203 is formed of an oxide semiconductor material, an auxiliary electrode including a metal or a transparent electrode material may be disposed in the remaining area except for the channel area of the active layer 303. The auxiliary electrode may be formed as a single layer or multilayer composed of any one of molybdenum (Mo), copper (Cu), titanium (Ti), aluminum (Al), chromium (Cr), gold (Au), nickel (Ni), and neodymium (Nd), or an alloy of them. The auxiliary electrode may be formed of the same material as the source electrode and the drain electrode of the thin film transistor.

Referring to FIG. 12, a second active pattern 322 may be disposed on the buffer layer 1202. The second active pattern 322 may be disposed in a portion of the second emission area EA2 and a portion of the non-emission area NEA. The second active pattern 322 may be formed of the same material as the active layer 1203, but is not limited thereto, and may be formed of a different material from the active layer 1203.

FIG. 12 illustrates a structure in which the second active pattern 322 is disposed on the buffer layer 1202, but the structure of the display panel 110 according to aspects of the disclosure is not limited thereto, and the first active pattern 321, the third active pattern 323, and the fourth active pattern 324 may also be disposed in a portion of the second emission area EA2.

As the second active pattern 322 is formed of a conductive oxide semiconductor material, the second active pattern 322 may not affect the aperture ratio even if it overlaps with the second emission area EA2 due to its transparent characteristics.

A gate insulation film 1204 may be disposed on the active layer 1203.

The gate insulation layer 1204 may include an inorganic insulating material such as silicon oxide (SiOx), silicon nitride (SiNx), and silicon oxynitride (SiON), but aspects of the disclosure are not limited thereto.

FIG. 12 illustrates a structure in which the gate insulation layer 1204 is disposed on a portion of the upper surface of the active layer 1203, but aspects of the disclosure are not limited thereto, and the gate insulation layer 1204 may be disposed while covering the active layer 1203.

A gate electrode 1205 of the thin film transistor may be disposed on the gate insulation film 1204.

The gate electrode 1205 may include any one of metals such as aluminum (Al), gold (Au), silver (Ag), copper (Cu), tungsten (W), molybdenum (Mo), chromium (Cr), tantalum (Ta), titanium (Ti), and an alloy thereof, but aspects of the disclosure are not limited thereto.

An inter-layer insulation layer 1206 may be disposed on the gate electrode 1205 and the second active pattern 321.

The inter-layer insulation layer 1206 may include an inorganic insulating material such as silicon oxide (SiOx), silicon nitride (SiNx), and silicon oxynitride (SiON), but aspects of the disclosure are not limited thereto.

A source electrode 1207 and a drain electrode 1208 of the thin film transistor may be disposed on the inter-layer insulation layer 1206 and may be spaced apart from each other.

In aspects of the disclosure, 1207 may be the drain electrode, and 1208 may be the source electrode.

The source electrode 1207 and the drain electrode 1208 may include any one of metals, such as aluminum (Al), gold (Au), silver (Ag), copper (Cu), tungsten (W), molybdenum (Mo), chromium (Cr), tantalum (Ta), and titanium (Ti), or alloys thereof, but aspects of the disclosure are not limited thereto.

Each of the source electrode 1207 and the drain electrode 1208 may be connected with a portion of the upper surface of the active layer 1203 through a contact hole provided in the inter-layer insulating layer 1206.

A planarization layer 1209 may be disposed on the substrate 1201 on which the source electrode 1207 and the drain electrode 1208 are disposed. The planarization layer 1209 may be made of an inorganic insulating material or an organic insulating material. Alternatively, the planarization layer 1209 may be made of a layer made of an organic insulating material and a layer made of an inorganic insulating material, which are stacked.

Although not illustrated in the drawings, a protection film including an inorganic insulating material such as silicon oxide (SiOx), silicon nitride (SiNx), or silicon oxynitride (SiON) may be further disposed under the planarization layer 1209.

The anode electrode AE of the light emitting element ED may be disposed on a portion of an upper surface of the planarization layer 1209.

The anode electrode AE may be electrically connected with the drain electrode 1208 of the thin film transistor through a contact hole provided in the planarization layer 1209. Although FIG. 12 illustrates a structure in which the anode electrode AE is connected with the drain electrode 1208 of the thin film transistor, the disclosure is not limited thereto, and the anode electrode AE may be connected with the source electrode 1207 of the thin film transistor.

A bank BK may be disposed on the planarization layer 1209. The bank BCK may be formed of a polyimide resin, an acrylic resin, or benzocyclobutene (BCB) resin, but is not limited thereto.

The bank BK may be disposed to overlap with a portion of the upper surface of the anode electrode AE. The bank BK may be disposed to expose a portion of the upper surface of the anode electrode AE.

The bank BK may define an emission area EA and a non-emission area NEA within the display area DA of the display panel 110. For example, the area in which the bank BK is disposed in the display area DA may be a non-emission area NEA, and the area in which the bank BK is not disposed in the display area DA may be an emission area EA.

Referring to FIG. 12, a portion of the second active pattern 322 overlapping with a portion of the non-emission area NEA may overlap with a portion of the bank BK.

A light emitting layer EL of a light emitting element ED may be disposed on the anode electrode AE.

The light emitting layer EL may be disposed on an upper surface of the anode electrode AE exposed by the bank BK.

Although FIG. 12 illustrates a structure in which the light emitting layer EL is a single layer, aspects of the disclosure are not limited thereto. The light emitting layer EL may be formed of a multi-layered organic layer.

A cathode electrode CE of a light emitting element ED may be disposed on the substrate 1201 on which the light emitting layer EL is disposed.

The anode electrode AE of the light emitting element ED may include a transparent conductive material such as ITO, IZO etc. The cathode electrode CE of the light emitting element ED may include a transparent conductive material or a semi-transmissive material such as magnesium (Mg), silver (Ag) or an alloy of magnesium (Mg) and silver (Ag).

The materials of the anode electrode AE and the cathode electrode CE of the light emitting element ED according to aspects of the disclosure are not limited thereto, and the anode electrode AE may include a reflective electrode formed of Al, Al alloy, Ag, Ag Alloy, Mg, Mg alloy or APC (Ag—Pd—Cu) and the like, and the cathode electrode CE may include a transparent conductive material.

In other words, the display panel 110 according to aspects of the disclosure may be applied to each of a bottom emission type, a top emission type, and a dual emission type.

The anode electrode AE may include a transparent conductive material, but aspects of the disclosure are not limited thereto.

Further, FIG. 12 illustrates a structure in which the anode electrode AE and the cathode electrode CE are a single layer, but the disclosure is not limited thereto, and the anode electrode AE and the cathode electrode CE may be formed in a multilayer structure of two or more layers.

An encapsulation layer 1230 may be disposed on the cathode electrode CE.

The encapsulation layer 1230 may include a first encapsulation layer 1231 disposed on the cathode electrode CE, a second encapsulation layer 1232 disposed on the first encapsulation layer 1231, and a third encapsulation layer 1233 disposed on the second encapsulation layer 1232. The first and third encapsulation layers 1231 and 1233 may include an inorganic insulating material such as silicon oxide (SiOx), silicon nitride (SiNx), or silicon oxynitride (SiON), and the second encapsulation layer 1232 may include an organic insulating material such as photo acryl or benzocyclobutene (BCB), but is not limited thereto.

Referring to FIG. 12, the second cutting line CL2 of the second active pattern 322 may be provided in an area overlapping with a portion of the second emission area EA2.

In other words, in the process of repairing the second subpixel SP2, a laser beam may be radiated to the second cutting line CL2 of the second active pattern 322 present in the second emission area EA2.

As illustrated in FIG. 12, as a separate color filter, electrode, or signal line is not disposed in the second emission area EA2, the process of radiating a laser beam to the second cutting line CL2 of the second active pattern 322 positioned in the second emission area EA2 may be easily performed.

According to aspects of the disclosure, there may be provided a display panel and a display device capable of preventing a reduction in opening area due to a repair pattern by using a transparent active pattern, which serves as a line, as the repair pattern.

According to aspects of the disclosure, there may be provided a display panel and a display device capable of preventing a reduction in success rate of repair process due to failure of a laser beam to arrive at the active pattern due to, e.g., a polarization plate included in the display device by performing a repair process using a long-wavelength laser beam and using a transparent active pattern as the repair pattern.

According to aspects of the disclosure, there may be provided a display panel and a display device capable of preventing a reduction in success rate of repair process due to failure of a laser beam to arrive at the active pattern due to the color filter as the repair of active pattern is performed on the emission area where the color filter is not disposed.

It will be apparent to those skilled in the art that various modifications and variations can be made in the display panel and the display device of the present disclosure without departing from the spirit or scope of the aspects. Thus, it is intended that the present disclosure covers the modifications and variations of the aspects provided they come within the scope of the appended claims and their equivalents.

What is claimed:

1. A display panel, comprising:
a substrate including a plurality of subpixels and including a plurality of emission areas and a non-emission area at the peripheral of the plurality of emission areas;
a plurality of signal lines disposed in the non-emission area of the substrate; and
at least one active pattern overlapping with a portion of at least one emission area among the plurality of emission areas and overlapping with a portion of the non-emission area,
wherein the active pattern includes at least one cutting line in an area corresponding to the plurality of emission areas with which it overlaps, and
wherein the active pattern is electrically connected to one of the plurality of signal lines and is electrically connected to at least one transistor disposed in the non-emission area at the peripheral of the plurality of emission areas where the active pattern is disposed.

2. The display panel of claim 1, wherein the active pattern includes a transparent oxide semiconductor material.

3. The display panel of claim 1, wherein the active pattern is conductive in at least a partial area.

4. The display panel of claim 1, wherein the plurality of signal lines include a reference voltage line,
wherein the active pattern is connected to the reference voltage line, and
wherein the active pattern is electrically connected to a sensing transistor disposed in the non-emission area.

5. The display panel of claim 1, wherein at least one of the plurality of emission areas includes a repair area, and
wherein the active pattern is corresponding to the repair area.

6. The display panel of claim 1, wherein the plurality of emission areas includes a first emission area, a second emission area, a third emission area, and a fourth emission area emitting different colors, and
wherein the active pattern includes a first active pattern disposed in a portion of the first emission area, a second active pattern disposed in a portion of the second emission area, a third active pattern disposed in a portion of the third emission area, and a fourth active pattern disposed in a portion of the fourth emission area.

7. The display panel of claim 6, wherein the first active pattern is electrically connected to a sensing transistor disposed in a first subpixel area, the second active pattern is electrically connected to a sensing transistor disposed in a second subpixel area, the third active pattern is electrically connected to a sensing transistor disposed in a third subpixel area, and the fourth active pattern is electrically connected to a sensing transistor disposed in a fourth subpixel area.

8. The display panel of claim 6, wherein each of the first to fourth active patterns includes at least one cutting line, and
wherein the cutting line of each of the first to fourth active patterns is disposed in an emission area where each of the first to fourth active patterns is disposed.

9. The display panel of claim 6, wherein each of the first to fourth active patterns includes at least one cutting line, and
wherein the cutting line of each of the first to fourth active patterns is disposed in one of the four emission areas.

10. The display panel of claim 9, wherein a color filter is not disposed in said one of the four emission areas, and
wherein color filters are disposed in the other three emission areas except said one emission area.

11. The display panel of claim 1, wherein a shape of the active pattern in an area overlapping with at least a portion of the emission area is different from a shape of the active pattern in an area overlapping with the non-emission area.

12. The display panel of claim 1, wherein the active pattern includes a plurality of protrusions and a plurality of depressions in a partial area overlapping with the emission area.

13. The display panel of claim 12, wherein each depression has a larger size than each protrusion.

14. The display panel of claim 12, wherein the plurality of protrusions and the plurality of depressions are provided on two opposite sides of the active pattern in an area overlapping with the emission area, and
wherein the plurality of protrusions and the plurality of depressions are disposed alternately with each other.

15. The display panel of claim 14, wherein at least a portion of a first depression disposed on one side surface of the active pattern is disposed to face at least a portion of a second depression disposed on another side of the active pattern, and wherein the at least one cutting lines includes a cutting line crossing the first and second depressions.

16. The display panel of claim 1, wherein a narrowest width of the active pattern in an area where a cutting area of the active pattern is present is narrower than a width of the active pattern in the non-emission area.

17. The display panel of claim 1, wherein the active pattern overlaps with a portion of at least one opaque pattern.

18. The display panel of claim 17, wherein there is a contact hole passing through which the signal line and the active pattern are electrically connected to each other on the opaque pattern.

19. The display panel of claim 1, wherein a portion of the active pattern overlaps with an opaque layer in the emission area, and
wherein the cutting line of the active pattern overlaps with the opaque layer.

20. The display panel of claim 1, wherein the at least one active pattern is disposed on the same layer as an active layer of a driving transistor.

21. The display panel of claim 5, wherein at least one of the first to fourth active patterns has a different shape from other active patterns
